(19) United States
(12) Patent Application Publication
(10) Pub. No.: US 2015/0152553 A1
(43) Pub. Date: Jun. 4, 2015

(54) ALD Coating System

(71) Applicant: OSRAM OLED GMBH, Regensburg (DE)

(72) Inventors: Michael Popp, Freising (DE); Marc Philippens, Regensburg (DE)

(73) Assignee: OSRAM OLED GmbH, Regensburg (DE)

(21) Appl. No.: 14/410,028

(22) PCT Filed: May 31, 2013
(86) PCT No.: PCT/EP2013/061233

§ 371 Date: Dec. 19, 2014

(30) Foreign Application Priority Data
Jun. 19, 2012 (DE) 102012210332.5

(51) Int. Cl. C23C 16/455; H01L 21/02; C23C 16/52

(52) U.S. Cl. CPC C23C 16/45544; C23C 16/52; C23C 16/45589; H01L 21/0262

(57) ABSTRACT

An atomic layer deposition (ALD) coating system and a method for depositing an ALD layer in the system are disclosed. In an embodiment an ALD coating system includes a storage container for an organometallic starting material and a device having a control valve, a pressure gage, a pressure diaphragm and a first multiway valve, wherein the device is arranged downstream of the storage container, and wherein the first multiway valve is switchable between a process chamber and a collecting chamber.

This patent application is a national phase filing under section 371 of PCT/EP2013/061233, filed May 31, 2013, which claims the priority of German patent application 10 2012 210 332.5, filed Jun. 19, 2012, each of which is incorporated herein by reference in its entirety.

### TECHNICAL FIELD

An ALD coating system and a method for operating an ALD coating system are provided.

### SUMMARY OF THE INVENTION

Embodiments of the invention provide an ALD coating system for coating a substrate comprising a semiconductor material, that is cost-efficient and material-saving. Other embodiments of the invention provide a stable and sustained supply of an organometallic starting material to a process chamber by a device.

According to at least one embodiment, the ALD coating system comprises a storage container for an organometallic starting material.

“Organometallic starting material”, also referred to as a precursor, is understood in the present context as meaning a reactive substance that may be in a liquid, solid and/or gaseous phase and, in particular, does not react with itself or ligands of itself. Furthermore, a decomposition of the organometallic starting material is possible, so that decomposition products or disintegration products can form. In other words, the organometallic starting material undergoes a self-limiting reaction. The organometallic starting material is stored in the storage container. For example, the organometallic starting material is in the storage container in a liquid, solid and/or gaseous phase. The storage container is pressure-stable and comprises a material that may in particular have a high thermal conductivity.

According to at least one embodiment of the ALD coating system, the ALD coating system has a device comprising a control valve, a pressure gage, a pressure diaphragm and a first multiway valve. The control valve, the pressure gage, the pressure diaphragm and the first multiway valve are connected to one another one after the other in a row, a series and/or a linear arrangement by way of a line to one another.

“Line” is understood in the present context as meaning a pipe or pipeline that is designed for transporting the organometallic starting material and can connect the individual constituent parts, components and/or elements of the ALD coating system to one another. The cross-sectional area of the lines described here may in this case have a round, angular or other uniform or nonuniform geometrical shape. “Cross-sectional area” is understood in the present context as meaning the lateral extent of the line formed perpendicularly or transversely in relation to a direction of flow of the organometallic starting material. The lines have in particular a diameter of ¼ inch to 2 inches and may be formed as straight, curved and/or angled, it being possible for the cross-sectional area to constantly increase and/or decrease in size.

With the control valve it is possible, for example, to control a feed of the gaseous organometallic material from the storage container into the device. This means that the amount of organometallic starting material that can in particular run, flow and/or pass through the device can be increased or reduced with the control valve. The way in which the control valve functions is determined by the pressure gage.

The pressure gage is arranged between the control valve and the pressure diaphragm and, during the operation of the ALD coating system, measures a working pressure of the organometallic starting material that can in particular build up between the storage container and the pressure diaphragm.

“Working pressure of the organometallic starting material” is understood as meaning in particular the vapor pressure of the organometallic starting material that can form during the operation of the ALD coating system.

The pressure diaphragm may be designed, for example, as a disk with an opening or multiple openings arranged within the disk, the sum of all the openings forming a surface area that is smaller than the cross-sectional area of the line between the pressure gage and the first multiway valve. For example, the sum of all the openings is less than the cross-sectional area of the line by more than 25%. The openings of the pressure diaphragm may be of a round and/or angular shape.

The control valve, the pressure gage, the pressure diaphragm and the first multiway valve respectively perform a function in the device and at least partially depend on one another with regard to the way in which they function. For example, the control valve is controlled by the pressure gage or the first multiway valve switches over between two lines during operation in a manner dependent on a value or dependent on the process step of the working pressure of the organometallic starting material that the pressure gage measures, determines and/or detects.

According to at least one embodiment, the device is arranged downstream of the storage container. In other words, a line is formed between the storage container and the device, the organometallic starting material being directed from the storage container in the direction of the device. The line between the storage container and the device may in particular be formed continuously. “Continuously” is understood in the present context as meaning that no interruption, a further line and/or a connecting piece, for example, in the form of a multiway valve, is formed in the line. The downstream connection of the device makes it possible, in particular during the operation of the ALD coating system, to control the working pressure of the organometallic starting material after leaving the storage container.

According to at least one embodiment, the first multiway valve can be switched between a process chamber and a collecting chamber. The first multiway valve is always open during the operation of the ALD coating system and directs the organometallic starting material either into the process chamber or into the collecting chamber. In other words, in particular during the operation of the ALD coating system, the further direction of the organometallic starting material depends on the working pressure of the organometallic starting material that is determined, measured and/or detected by the pressure gage.

According to at least one embodiment of the ALD coating system, the first multiway valve switches alternately into the process chamber and collecting chamber so quickly that there is no visible pressure fluctuation in the pressure control by the device. The pressure control by the device consequently takes place virtually continuously or continuously.

According to at least one embodiment of an ALD coating system, the ALD coating system comprises a storage container for an organometallic starting material and a device comprising a control valve, a pressure gage, a pressure diaphragm and a first multiway valve, the device being arranged downstream of the storage container, in particular in the direction of a material flow, and the first multiway valve being switchable between a process chamber and a collecting chamber.

By means of ALD coating systems for atomic layer deposition (ALD), very thin functional layers, for example, layer thicknesses of 0.1 to 3 Å, can be produced. It is possible here for the above layer thicknesses to correspond in particular to the layer thickness of an atomic layer.

The term “atomic layer deposition” is understood here as meaning the production of a layer, the organometallic starting materials that are necessary for this not being fed at the same time, but alternately one after the other, to the process chamber, the coating chamber and/or the reactor with the substrate to be coated. The organometallic starting materials can in this case be adsorbed alternately on the surface of the substrate to be coated or on the previously deposited starting material, and thereby enter into a bond. This makes it possible that, with every repetition of the cycle, that is to say the one-off feeding of all the necessary organometallic starting materials in sub-steps following one after the other, each time at most a monolayer of the layer to be applied can be grown on, so that it is possible to keep a good check on the layer thickness by the number of cycles.

Furthermore, the ALD coating system described here has the advantage that, as a result of the fact that the first-fed organometallic starting material is only adsorbed on the surface to be coated and it is only the then-fed second starting material that undergoes reactions with the first starting material, a very conformal layer growth is possible, allowing even surfaces with a great aspect ratio to be covered uniformly.

Organometallic starting materials are stored in temperature-stabilized storage containers, in order to feed them to the process chamber as and when required. Depending on the temperature in the storage container, the organometallic starting material is also partly in a gaseous phase over the organometallic starting material that is in liquid form and/or solid form. The storage container is mounted in a thermostatic bath, which has as great a thermal capacity as possible, in order to keep the temperature of the starting material in the storage container as constant as possible. The temperature-stabilized storage container has at least one line, through which the gaseous starting material is fed by pulse-like, surge-like and/or cyclical opening of a multiway valve to a gas stream, which carries the material to the coating chamber. Corresponding to the vapor pressure, which is determined by the temperature of the organometallic starting material, and consequently at least in principle by the temperature of the thermostatic bath, a certain amount of the starting material enters the gas stream.

On account of the pulse-like removal of the organometallic starting material from the storage container, temperature fluctuations within the organometallic starting material that remains in the storage container occur in dependence on the duration and frequency of the removal and the geometrical conditions of the storage container. A temperature regeneration can usually only be achieved partially, since the thermal transfer from the thermostatic bath to the organometallic starting material in the storage container partly proceeds only very slowly or sluggishly. As a result, in the course of multiple coating cycles there is an undefined cooling of the organometallic starting material in the storage container. In other words it is possible in particular to measure a temperature gradient within the storage container.

The undefined cooling of the organometallic starting material in the storage container in dependence on the length and frequency of the coating cycles and in dependence on the size of the storage container may lead to a nonuniform layer thickness profile of the layers to be applied, whereby the quality of the layers to be applied within the production tolerance of the ALD coating system may also be affected.

In this respect, so far only the temperature has been measured and controlled, while stabilization of the vapor pressure of the organometallic starting material takes place indirectly by way of thermostatic baths, which however, on account of the sluggish heat transfer, lead to the temperature fluctuations and gradients in the storage container referred to. The problem of scaling the size of storage containers appears so far to be unresolved.

In order to provide an ALD coating system in which the feeding of the organometallic starting material has a constant or stable material flow in spite of possible temperature gradients in the storage container, the ALD coating system described here makes use of the idea of connecting in particular the device described above downstream of the storage container, so that, during operation, the organometallic starting material is only directed into the process chamber as from the required working pressure of the organometallic starting material. The working pressure is kept constant over time by the device, in particular during operation of the ALD coating system.

“Constant over time” is understood in the present context as meaning that the working pressure is kept stable, uniform and/or with little fluctuation about a mean value of the working pressure within a measuring tolerance by the device. The pressure difference may deviate from the required and/or suitable working pressure or mean value of the working pressure by between 1 and 2%, in particular by less than 1% or by less than 1‰.

If the working pressure for processing the process chamber or carrying out the atomic layer deposition changes, the organometallic starting material is directed into the collecting chamber in particular through the first multiway valve. The feeding into the collecting chamber then continues until the working pressure of the organometallic starting material that is kept constant over time by the device for carrying out the atomic layer deposition is restored in the device.

According to at least one embodiment of the ALD coating system, the pressure gage controls with the control valve a constant-over-time working pressure of the organometallic starting material between the storage container and the pressure diaphragm. That is to say that the pressure gage controls the control valve in a manner dependent on the constant-over-time working pressure of the organometallic starting material, the pressure gage measuring the constant-over-time working pressure of the organometallic starting material between the storage container and the pressure diaphragm. In other words, it is a dynamic pressure control of the working pressure of the organometallic starting material, which can be measured between the storage container and the pressure diaphragm. The pressure gage is arranged downstream of the control valve, in particular in the direction of a material flow.

If the pressure gage measures an insufficient working pressure of the organometallic starting material to direct the latter into the process chamber by way of the first multiway valve, organometallic starting material is fed to an increased extent in the direction of the pressure diaphragm by way of the control valve. If the pressure gage measures the working pressure of the organometallic starting material that is suitable for processing the process chamber, the feeding of the organometallic starting material is restricted and/or reduced.

The pressure diaphragm is arranged between the pressure gage and the first multiway valve. With the pressure diaphragm, a reduction in size of the line cross section or of the line diameter occurs in particular, and the working pressure of the organometallic starting material upstream of the pressure diaphragm rises. The pressure diaphragm allows in particular the rise in the working pressure of the organometallic starting material within the device to be measured by the pressure gage. In other words, the pressure diaphragm allows a constant working pressure to be ensured by intercepting, compensating for and/or balancing out in particular the fluctuations of the working pressure in the storage container by the pressure diaphragm. That is to say that, during the operation of the ALD coating system, the pressure formed downstream of the pressure diaphragm cannot go below a minimum pressure.

According to at least one embodiment of the ALD coating system, a constant-over-time working pressure of the organometallic material that is greater than the working pressure of the organometallic material in the storage container occurs between the pressure gage and the pressure diaphragm. On account of the decrease in size of the cross-sectional area of the line as a result of the pressure diaphragm, the working pressure of the organometallic starting material directly upstream of the pressure diaphragm builds up. The working pressure is preferably kept constant over time by the device during the operation of the ALD coating system. The thereby resultant constant-over-time working pressure of the organometallic starting material is greater than the working pressure of the organometallic starting material in the storage container. The constant-over-time working pressure of the organometallic starting material upstream of the pressure diaphragm can be ensured in particular by the pressure gage and the control valve of the device. If the constant-over-time working pressure of the organometallic starting material upstream of the pressure diaphragm changes, the control valve is controlled by way of the pressure gage in such a way that more of the organometallic starting material is directed out of the storage container into the device.

According to at least one embodiment of the ALD coating system, the first multiway valve switches into the process chamber when the constant-over-time working pressure of the organometallic starting material is present between the pressure gage and the pressure diaphragm and the first multiway valve switches into the collecting chamber when there is a working pressure of the organometallic starting material that deviates from the constant-over-time working pressure. The first multiway valve is therefore open during the operation of the ALD coating system and, depending on the working pressure of the organometallic starting material, directs the organometallic starting material either into the process chamber or into the collecting chamber. The switching of the first multiway valve between the process chamber and the collecting chamber does not influence the constant-over-time working pressure of the organometallic starting material that can form between the pressure gage and the pressure diaphragm. In other words, the conductance of the organometallic starting material is not changed, in particular reduced, by the switching of the first multiway valve. “Conductance” is understood in the present context as meaning the reciprocal value of the line resistance.

According to at least one embodiment of the ALD coating system, the collecting chamber has a widening in diameter of 5 to 10 times in comparison with the lines of the ALD coating system, which may in particular have a diameter of ¼ inch to 2 inches. The widening of the diameter described above does not have the effect of influencing in particular the constant-over-time working pressure between the pressure diaphragm and the first multiway valve during the feeding of the organometallic starting material into the collecting chamber.

According to at least one embodiment of the ALD coating system, a second multiway valve is arranged between the storage container and the device and a third multiway valve is arranged between the device and the collecting chamber. That is to say that the lines between the storage container and the device and between the device and the collecting chamber each have a multiway valve. The second and third multiway valves are fitted in the lines in such a way that in particular no pressure drop of the working pressure of the organometallic starting material can take place. The second multiway valve may in particular direct the organometallic starting material into the device or into at least one further line. The third multiway valve may in particular direct the organometallic starting material out of the device into the collecting chamber or be connected to at least one further line.

According to at least one embodiment of the ALD coating system, the second multiway valve is connected to the third multiway valve. The line that connects the second multiway valve to the third multiway valve may in particular pass around the device. That is to say that the organometallic starting material can leave the storage container and be directed directly into the collecting chamber without passing through the device. In other words, the line between the second multiway valve and the third multiway valve is formed, for example, as a bypass.

According to at least one embodiment of the ALD coating system, a discharge of disintegration products of the organometallic starting material directly into the collecting chamber takes place by way of the second multiway valve and the third multiway valve. The organometallic starting material forms in the storage container in particular disintegration products, waste products and/or undesired products that have a higher vapor pressure than the organometallic starting material. In other words, there may form in particular in the storage container disintegration products which, on account of their higher vapor pressure, overlie the organometallic starting material that is in a gaseous phase and which are in a gaseous form in the storage container.

The opening of the second multiway valve and the third multiway valve allows the disintegration products to be removed, pumped and/or sucked away from the storage container during and after the processing in the process chamber. The discharge of the disintegration products of the organometallic starting material by way, for example, of the bypass described above, which may be formed between the second multiway valve and the third multiway valve, can be speeded up by the use of a line with a greater diameter. That is to say that the line between the second multiway valve and the third multiway valve may have a greater diameter than most of the lines that are fitted, present and/or used in the ALD coating system, with a diameter of, for example, ¼ inch to 2 inches. For example, the line fitted in the bypass may be 2 inches, while further lines of the ALD coating system have a diameter of 1 inch.

According to at least one embodiment of the ALD coating system, a fourth, fifth and sixth multiway valve are arranged between the first multiway valve and the process chamber, the fourth and sixth multiway valves being located on a same line to the process chamber, taken from the first multiway valve, and the sixth multiway valve being arranged downstream of the fourth multiway valve, taken from the first multiway valve, in particular in the direction of a material flow. Furthermore, the fifth multiway valve is located on a line between the fourth and sixth multiway valves and a gas-metering element for feeding a carrier gas and/or purging gas is arranged downstream of the fifth multiway valve.

The first multiway valve directs a working pressure of the organometallic starting material that is in particular kept constant over time by the device further in the direction of the process chamber. In the line between the first multiway valve and the process chamber, in particular a fourth, fifth and sixth multiway valve may be arranged in such a way that the pulse-like feeding of the organometallic starting material into the process chamber does not have to be controlled by the switching of the first multiway valve alone. That is to say that a pulse-like feeding of the organometallic starting material into the process chamber can be controlled by closing and/or opening of the fourth and sixth multiway valves, without the first multiway valve having to be switched in the direction of the collecting chamber.

Furthermore, the fourth multiway valve may be closed during operation. The line that is formed between the fourth and sixth multiway valves allows the fifth multiway valve to be connected to the gas-metering element. Using the gas-metering element, in particular a purging gas can be directed into the process chamber in a metered manner by way of the fifth and sixth multiway valves. The purging gas is in particular an inert gas. For example, the purging gas may comprise argon or some other inert gas.

The supplying of the process chamber with the purging gas may take place before, during and after the processing in the process chamber. In particular, the purging gas is used for cleaning the process chamber before, during and after the atomic layer deposition.

Furthermore, a carrier gas may be directed into the line to the process chamber by way of the line in which the fifth multiway valve is formed. The carrier gas is used in particular for transporting the organometallic starting material that is in the gaseous phase, it being possible for this to be advantageous, for example, if the line between the first multiway valve and the process chamber is formed with such a length that the carrier gas allows the transportation of the organometallic starting material into the process chamber to be speeded up.

According to at least one embodiment of the ALD coating system, a vacuum pump is arranged downstream of the collecting chamber, in particular in the direction of a material flow. As already described above, decomposition products can be directed into the collecting chamber. This takes place in particular through the bypass, which bypasses the device and is connected by the second and third multiway valves. In the collecting chamber there may have formed a vacuum, which can be produced by the vacuum pump. In other words, a negative pressure is produced in the collecting chamber by the vacuum pump. The negative pressure has the effect of forming a vacuum, which at least according to one embodiment has the same negative pressure as may be formed in the process chamber. The pressure difference between the device and the collecting chamber or the process chamber may be, for example, 10-3 to 10-6 mbar.

The conductance of the organometallic starting material is not reduced and switching of the first multiway valve in the direction of the process chamber or in the direction of the collecting chamber does not influence the working pressure between the pressure diaphragm and the first multiway valve as a result of the negative pressure in the collecting chamber.

According to at least one embodiment of the ALD coating system, the collecting chamber is pumped out by the vacuum pump continuously or at regular time intervals, in particular continually, during operation. In this way it is possible that the collecting chamber remains substantially free from organometallic material.

According to at least one embodiment of the ALD coating system, multiple devices of the type described above are arranged on a process chamber. In other words, the process chamber can at one and the same time be supplied with further organometallic starting materials, connected and/or switched and is not restricted to a single instance of being fed with the organometallic starting material that is described here.

A method for operating an ALD coating system for growing at least one layer on a substrate in accordance with one of the previous embodiments of the ALD coating system is described below. The method is suitable in particular for operating an ALD coating system described here. All of the features described for the ALD coating system are disclosed for the method, and vice versa.

According to at least one embodiment of the method for operating an ALD coating system for growing at least one layer on a substrate, the method comprises the following steps:
providing the organometallic starting material in the storage container,
feeding the organometallic starting material into the device,
directing the organometallic starting material further into the process chamber or into the collecting chamber by the switchable first multiway valve.

The organometallic starting material that is in the gaseous phase in the storage container is fed into the device of the ALD coating system described above. The organometallic starting material, which passes, runs and/or flows through the device, is then directed by the first multiway valve into the process chamber or into the collecting chamber.

According to at least one embodiment of the method, the organometallic starting material is provided in the device with a working pressure that is constant over time. In other words, the organometallic starting material is only directed into the process chamber by the first multiway valve when the pressure gage detects a constant-over-time working pressure of the organometallic starting material that is required and/or suitable for carrying out the atomic layer deposition in the process chamber.

According to at least one embodiment of the method, the purging gas flows into the process chamber by way of the fifth and sixth multiway valves and the gas-metering element, and the fourth multiway valve is closed. That is to say that the process chamber is not supplied with the organometallic starting material and can be cleaned by the purging gas by way of the fifth and sixth multiway valves before, during and/or after the operation of the ALD coating system. The closing of the fourth multiway valve can be bypassed during operation by switching the first multiway valve in the direction of the collecting chamber. If the process chamber is to be cleaned during operation and if the first multiway valve is switched to the process chamber, the closing of the fourth multiway valve cannot be bypassed.

According to at least one embodiment of the method, the fourth multiway valve is opened, and the fifth and sixth multiway valves are closed, so that the organometallic starting material is directed from the direction of the first multiway valve up to the sixth multiway valve. In other words, the above state describes the ALD coating system during operation. That is to say that the bypass for carrying away the disintegration products is closed and the first multiway valve is switched in the direction of the process chamber. Furthermore, the fifth multiway valve for feeding the purging gas is closed. The organometallic starting material is directed up to the sixth multiway valve and has a constant-over-time working pressure, which has been controlled, produced or directed in the direction of the sixth multiway valve by the upstream device. Closing and opening of the sixth multiway valve allows the pulse-like feeding of the organometallic starting material to be achieved. Between closing and opening of the sixth multiway valve, there may elapse, for example, between 1 and 10 seconds.

The pulse-like feeding of the organometallic starting substance may also take place directly by way of the first multiway valve, the fourth and sixth multiway valves being open. The fifth multiway valve may be closed or open, in the open state a carrier gas allowing the transportation of the organometallic starting material to be assisted, speeded up or stabilized.

### BRIEF DESCRIPTION OF THE DRAWINGS

The ALD coating system described here and the method for operating an ALD coating system for growing on at least one substrate are explained below on the basis of exemplary embodiments with associated figures.

Elements that are the same, of the same type or act in the same way are provided with the same designations in the figures. The figures and the relative sizes of the elements represented in the figures with respect to one another are not to be considered as true to scale. Rather, individual elements may be shown exaggerated in size for the sake of better representation and/or better understanding.

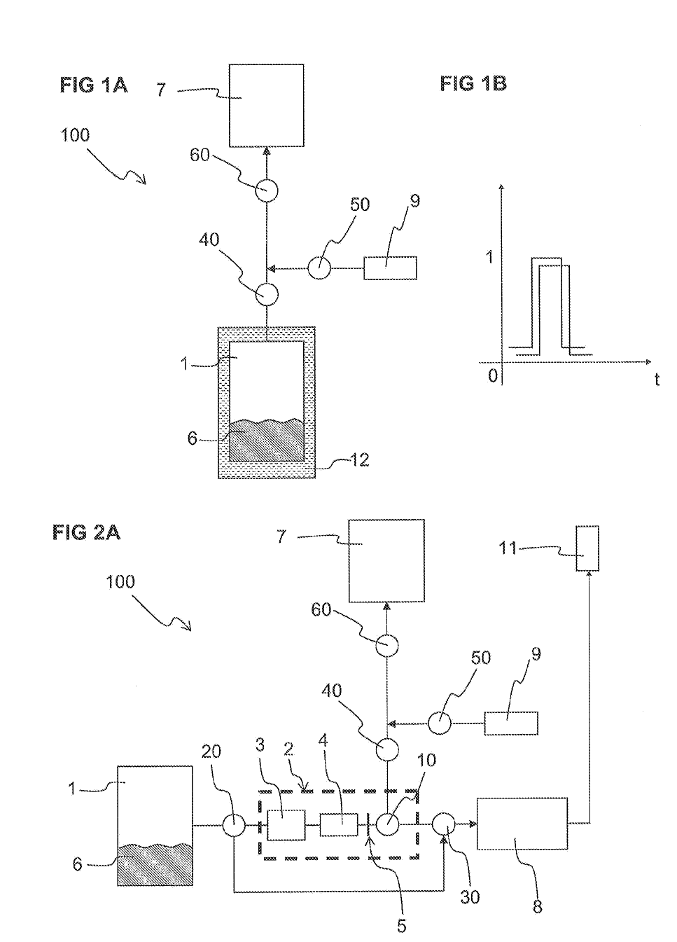

Exemplary embodiments of the ALD coating system described here and the method for operating an ALD coating system are explained in more detail on the basis of the schematic representations of FIGS. 1A, 1B and also 2A, 2B and 2C.

### DETAILED DESCRIPTION OF ILLUSTRATIVE EMBODIMENTS

In the exemplary embodiment of FIG. 1A, an ALD coating system 100 is schematically shown without the device described here.

In the ALD coating system 100 of FIG. 1A, an organometallic starting material 6 is stored in a temperature-stabilized storage container 1, in order to feed it to the process chamber 7 as and when required, the organometallic starting material 6 also partly being in a gaseous phase over the liquid and/or solid matter, depending on the temperature in the storage container 1. The storage container 1 is mounted in a thermostatic bath 12, which has as great a thermal capacity as possible, in order to keep the temperature of the organometallic starting material 6 in the storage container as constant as possible. The organometallic starting substance in the gaseous phase that forms in the storage container is then directed into the process chamber 7 by way of a line in which a fourth and a sixth multiway valve 40, 60 are located, while connected between the fourth multiway valve 40 and the sixth multiway valve 60 there is a further line, which comprises a fifth multiway valve 50 and a gas-metering element 9. The fifth multiway valve 50 is supplied with a purging gas and/or carrier gas by way of the gas-metering element 9.

Through the line, the gaseous starting material 6 of the temperature-stabilized storage container 1 is fed by pulse-like, surge-like and/or cyclical opening of a multiway valve 40, 60 to a gas stream, which carries the organometallic starting material 6 to the process chamber 7. Corresponding to the vapor pressure, which is determined by the temperature of the organometallic starting material 6, and consequently at least in principle by the temperature of the thermostatic bath 12, a certain amount of the organometallic starting material 6 enters the gas stream.

On account of the pulse-like removal of the organometallic starting material 6 from the storage container 1, temperature fluctuations within the organometallic starting material that remains in the storage container 1 occur in dependence on the duration and frequency of the removal and the geometrical conditions of the storage container 1. A temperature regeneration can usually only be achieved partially, since the thermal transfer from the thermostatic bath 12 to the organometallic starting material 6 in the storage container 1 partly proceeds only very slowly or sluggishly. As a result, in the course of multiple coating cycles there is an undefined cooling of the organometallic starting material 6 in the storage container 1. In other words it is possible to measure a temperature gradient within the storage container 1.

The undefined cooling of the organometallic starting material 6 in the storage container 1 in dependence on the length and frequency of the coating cycles and in dependence on the size of the storage container 1 may lead to a nonuniform layer thickness profile of the layers to be applied, whereby the quality of the layers to be applied within the production tolerance of the ALD coating system 100 may also be affected.

In this respect, so far only the temperature has been measured and controlled, stabilization of the vapor pressure of the organometallic starting material 6 taking place indirectly by way of thermostatic baths 12, which however, on account of the sluggish heat transfer, lead to the temperature fluctuations and gradients in the storage container 1 referred to. The problem of scaling the size of storage containers appears so far to be unresolved.

In FIG. 1B, the pulse-like feeding of the gaseous organometallic starting material 6 is schematically represented on the basis of a diagram. With reference to FIG. 1A, this can be realized by opening and closing of the fourth and/or sixth multiway valves 40, 60. 0 means that the respective multiway valve 40, 60 or the multiway valves 40, 60 in combination is/are closed and 1 means that one or more multiway valves 40, 60 in combination is/are in the open state of the ALD coating system. The time axis t indicates here a time interval between opening and closing of the at least one multiway valve. Feeding of the carrier gas and/or of the purging gas by way of the gas-metering element 9 can also take place in a pulse-like manner with the fifth multiway valve 50. The multiway valves 40, 50, 60 may all be opened and closed at the same time, while in particular slightly offset opening and closing of the multiway valves is also possible.

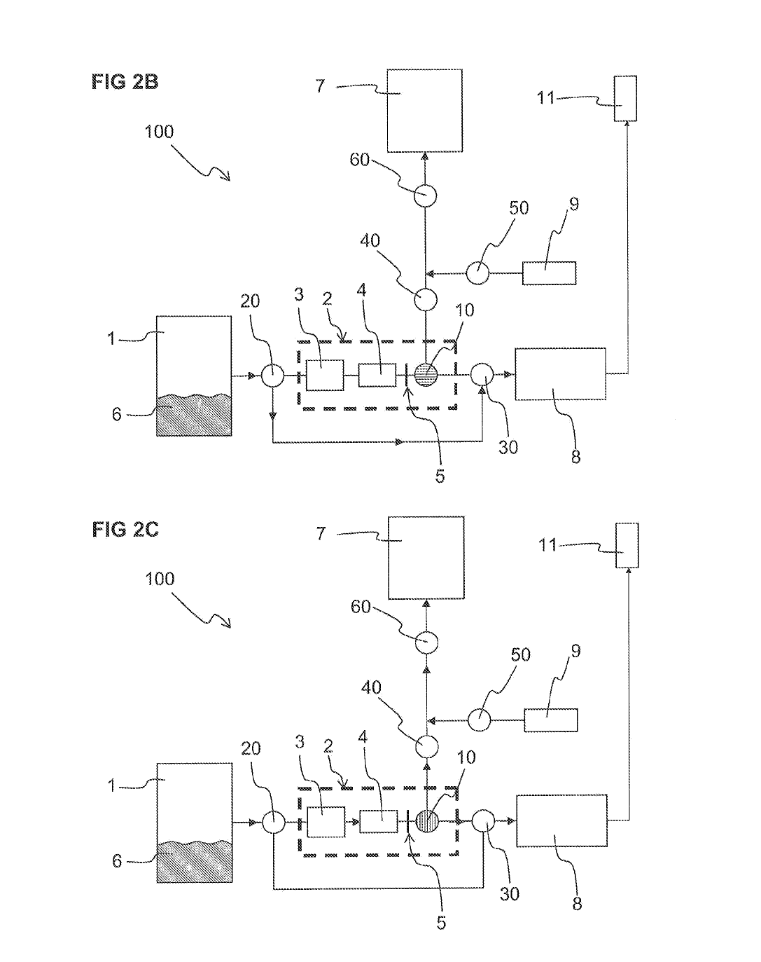

Schematically represented in FIG. 2A is the exemplary embodiment of FIG. 1A supplemented by a device 2 described here, comprising a control valve 3, a pressure gage 4, a pressure diaphragm 5 and a first multiway valve 10. Also schematically represented is a bypass by way of a second multiway valve 20 and a third multiway valve 30 for the direct discharge of the disintegration products of the organometallic starting material 6 into a collecting chamber 8. The collecting chamber 8 with the downstream vacuum pump 11 is in turn arranged downstream of the first multiway valve 10. Before the ALD coating system shown in FIG. 2A is put into operation, disintegration products can be discharged directly into the collecting chamber 8 by way of the bypass that is formed between the second multiway valve and the third multiway valve.

The organometallic material 6 in the gaseous phase leaves the storage container 1 in the direction of the device 2 and builds up between the pressure gage 4 and the pressure diaphragm 5 a working pressure that is constant over time and is greater than the working pressure in the storage container. Once the constant-over-time working pressure has been reached, the first multiway valve 10 is opened in the direction of the process chamber 7, the fourth and sixth multiway valves 40, 60 being switched in relation to one another in such a way that a pulse-like feeding of the organometallic starting material 6 into the process chamber 7 takes place. Through the line with the fifth multiway valve 50, a carrier gas or a purging gas can be directed into the line between the first multiway valve 10 and the process chamber 7.

In the exemplary embodiment of FIG. 2B, the state of the ALD coating system 100 before formation or processing of the layers in the process chamber 7 is schematically shown. Before the beginning of the deposition, disintegration products of the organometallic starting material are directed directly into the collecting chamber 8 while bypassing the device 2 by repeated brief opening of the second and third multiway valves 20, 30. Furthermore, by opening the fifth and sixth multiway valves 50, 60, before it is taken into operation the process chamber 7 can be cleaned and/or purged with a purging gas before, during and after the deposition. The sixth multiway valve 60 may be placed in particular directly upstream of the process chamber. That is to say that, in FIG. 2B, the multiway valves 20, 30, 40, 50, 60 are closed or open in such a way that the storage container is freed of disintegration products and the process chamber is cleaned by a purging gas. In other words, in FIG. 2B no organometallic starting material 6 is directed through the device 2.

In FIG. 2C, the ALD coating system 100 during operation is schematically represented. The second and third multiway valves 20, 30 are closed and the second multiway valve 20 directs the organometallic starting material into the device 2. The first multiway valve is always open and, depending on the working pressure, which is measured at the pressure gage 4 and is controlled by the control valve 3, switches between the process chamber 7 and the collecting chamber 8. The fourth multiway valve 40 is open and directs the organometallic starting material fed from the first multiway valve 10 up to the closed sixth multiway valve 60. By opening and closing of the sixth multiway valve 60, the process chamber 7 is supplied with the organometallic starting material in a pulse-like manner for the forming of a layer on a substrate.

The invention is not restricted by the description on the basis of the exemplary embodiments to these embodiments. Rather, the invention comprises every novel feature and every combination of features, which includes in particular any combination of features in the patent claims, even if this feature or this combination itself is not explicitly specified in the patent claims or exemplary embodiments.

1-11. (canceled)

12. An ALD coating system comprising:
a storage container for an organometallic starting material; and
a device comprising a control valve, a pressure gage, a pressure diaphragm and a first multiway valve,
wherein the device is arranged downstream of the storage container, and
wherein the first multiway valve is switchable between a process chamber and a collecting chamber.

13. The ALD coating system according to claim 12, wherein the pressure gage and the control valve control a constant-over-time working pressure of the organometallic starting material between the storage container and the pressure diaphragm.

14. The ALD coating system according to claim 12, wherein the device is configured to provide a constant-over-time working pressure of the organometallic starting material that is greater than a working pressure of the organometallic starting material in the storage container between the pressure gage and the pressure diaphragm.

15. The ALD coating system according to claim 14, wherein the first multiway valve switches into the process chamber when the constant-over-time working pressure of the organometallic starting material is present between the pressure gage and the pressure diaphragm, and wherein the first multiway valve switches into the collecting chamber when a working pressure of the organometallic starting material deviates from the constant-over-time working pressure.

16. The ALD coating system according to claim 12, further comprising:
a second multiway valve arranged between the storage container and the device; and
a third multiway valve arranged between the device and the collecting chamber,
wherein the second multiway valve is connected to the third multiway valve, and
wherein a discharge of disintegration products of the organometallic starting material is directly directed into the collecting chamber by the second multiway valve and the third multiway valve.

17. The ALD coating system according to claim 12, further comprising a fourth, fifth and sixth multiway valve arranged between the first multiway valve and the process chamber,
wherein the fourth and sixth multiway valves are located on a same line to the process chamber, taken from the first multiway valve, and wherein the sixth multiway valve is arranged downstream of the fourth multiway valve,
wherein the fifth multiway valve is located on a line between the fourth and sixth multiway valves, and
wherein a gas-metering element for feeding a carrier gas and/or purging gas is arranged downstream of the fifth multiway valve.

18. The ALD coating system according to claim 12, further comprising a vacuum pump arranged downstream of the collecting chamber.

19. A method for operating an ALD coating system for growing at least one layer on a substrate, the method comprising:
providing the ALD coating system according to claim 12;
providing the organometallic starting material in the storage container;
feeding the organometallic starting material into the device; and
directing the organometallic starting material further into the process chamber or into the collecting chamber by the switchable first multiway valve.

20. The method according to claim 19, wherein the organometallic starting material is provided in the device with a working pressure that is constant over time.

21. The method according to claim 19, wherein a purging gas flows into the process chamber by fifth and sixth multiway valves and a gas-metering element, and wherein a fourth multiway valve is closed.

22. The method according to claim 19, wherein a fourth multiway valve is opened, and wherein fifth and sixth multiway valves are closed so that the organometallic starting material is directed from the direction of the first multiway valve up to the sixth multiway valve.

23. An ALD coating system comprising:
a storage container for an organometallic starting material; and
a device comprising a control valve, a pressure gage, a pressure diaphragm and a first multiway valve,
wherein the device is arranged downstream of the storage container,
wherein the first multiway valve is switchable between a process chamber and a collecting chamber,
wherein the device is configured to provide a constant-over-time working pressure of the organometallic starting material that is greater than a working pressure of the organometallic starting material in the storage container between the pressure gage and the pressure diaphragm,
wherein the first multiway valve switches into the process chamber when the constant-over-time working pressure of the organometallic starting material is present between the pressure gage and the pressure diaphragm, and
wherein the first multiway valve switches into the collecting chamber when a working pressure of the organometallic starting material deviates from the constant-over-time working pressure.

24. A method for operating an ALD coating system for growing at least one layer on a substrate, the method comprising:
providing a ALD coating system with a storage container for an organometallic starting material and a device comprising a control valve, a pressure gage, a pressure diaphragm and a first multiway valve, wherein the device is arranged downstream of the storage container, and wherein the first multiway valve is switchable between a process chamber and a collecting chamber;
providing the organometallic starting material in the storage container;
feeding the organometallic starting material into the device; and
directing the organometallic starting material into the process chamber or into the collecting chamber by the switchable first multiway valve.

25. The method according to claim 24, wherein the organometallic starting material is provided in the device with a working pressure that is constant over time.

26. The method according to claim 24, wherein a purging gas flows into the process chamber by fifth and sixth multiway valves and a gas-metering element, and wherein a fourth multiway valve is closed.

27. The method according to claim 24, wherein a fourth multiway valve is opened, and wherein fifth and sixth multiway valves are closed so that the organometallic starting material is directed from the direction of the first multiway valve up to the sixth multiway valve.

28. The method according to claim 24, wherein the pressure gage and the control valve control a constant-over-time working pressure of the organometallic starting material between the storage container and the pressure diaphragm.

29. The method according to claim 24, wherein a constant-over-time working pressure of the organometallic starting material that is greater than a working pressure of the organometallic starting material in the storage container occurs between the pressure gage and the pressure diaphragm.

30. The method according to claim 29, wherein the first multiway valve switches into the process chamber when the constant-over-time working pressure of the organometallic starting material is present between the pressure gage and the pressure diaphragm, and wherein the first multiway valve switches into the collecting chamber when a working pressure of the organometallic starting material deviates from the constant-over-time working pressure.

31. The method according to claim 24, further comprising:
a second multiway valve arranged between the storage container and the device; and
a third multiway valve arranged between the device and the collecting chamber,
wherein the second multiway valve is connected to the third multiway valve, and wherein
a discharge of disintegration products of the organometallic starting material is directly directed into the collecting chamber by the second multiway valve and the third multiway valve.

32. The method according to claim 24, further comprising fourth, fifth and sixth multiway valves arranged between the first multiway valve and the process chamber,
wherein the fourth and sixth multiway valves are located on a same line to the process chamber, taken from the first multiway valve,
wherein the sixth multiway valve is arranged downstream of the fourth multiway valve,
wherein the fifth multiway valve is located on a line between the fourth and sixth multiway valves, and
wherein a gas-metering element for feeding a carrier gas and/or purging gas is arranged downstream of the fifth multiway valve.

33. The method according to claim 24, wherein a vacuum pump is arranged downstream of the collecting chamber.
